(19) United States
(12) Patent Application Publication
(10) Pub. No.: US 2006/0170087 A1
(43) Pub. Date: Aug. 3, 2006

(54) Semiconductor device

(75) Inventor: Hideki Nakajima, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/332,256

(22) Filed: Jan. 17, 2006

(30) Foreign Application Priority Data
Jan. 31, 2005 (JP) 2005-023471

(51) Int. Cl. H01L 23/02

(52) U.S. Cl. 257/678

(57) ABSTRACT

A semiconductor device according to the present invention includes a substrate having interconnections thereon, a first semiconductor chip mounted on the substrate such that the device formation surface thereof is faced to the substrate and a second semiconductor chip mounted on the first semiconductor chip, wherein an interconnection layer is provided on the back surface of said first semiconductor chip which is faced to said second semiconductor chip and the interconnection layer is electrically connected to the interconnections on said substrate.

This application is based on Japanese patent application NO. 2005-023471, the content of which is incorporated hereinto by reference.

### BACKGROUND

1. Technical Field

The present invention relates to a semiconductor device.

2. Related Art

In recent years, there has been advanced development of semiconductor devices having stack-type MCP (Multi Chip Package) structures and SIP (System in Package) structures including plural semiconductor chips stacked into a single package. As such semiconductor devices, there is a semiconductor device described in Japanese Laid-open patent publication NO. 2001-7278, for example. FIG. 7A illustrates a schematic cross-sectional view of the semiconductor device described in the same document. This semiconductor device 100 has a structure including a first semiconductor chip 104, an interconnection sheet 106 and a second semiconductor chip 108 which are stacked in the mentioned order on a substrate 102 having interconnections thereon. The substrate 102 includes, on the surface thereof at one side, solder balls 110 which are connecting members used for mounting it onto a printed circuit board. Further, on the mounting surface 102a of the substrate 102 which is the opposite surface, the first semiconductor chip 104 is flip-chip-mounted through bumps such that the device formation surface 104a is faced to the substrate 102.

The interconnection sheet 106 is mounted on the back surface 104b of the first semiconductor chip 104. The interconnection sheet 106 includes, at its upper surface, an interconnection surface 106a including bonding pads (not shown) for establishing electrical connection with the second semiconductor chip 108, bonding pads (not shown) for establishing electrical connection with the interconnections on the substrate 102 and an interconnection pattern for connecting these bonding pads to one another. On the interconnection surface 106a, the second semiconductor chip 108 is mounted such that the device formation surface 108a thereof is upwardly faced.

The second semiconductor chip 108 is provided, on the device formation surface 108a thereof, with bonding pads (not shown). The interconnection sheet 106 is provided, on the interconnection surface 106a thereof, with bonding pads (not shown). These bonding pads are electrically connected through bonding wires 112. The interconnection sheet 106 and the interconnections on the substrate 102 are electrically connected through bonding wires 113 similarly. Accordingly, the second semiconductor chip 108 and the interconnections on the substrate 102 are electrically connected through the interconnection sheet 106. Also, as illustrated in FIG. 7B, the second semiconductor chip 108 may be flip-chip-mounted on the interconnection surface 106a of the interconnection sheet 106. The first semiconductor chip 104, the interconnection sheet 106 and the second semiconductor chip 108 which have been stacked on the substrate 102 are molded by an encapsulating resin 114.

### SUMMARY OF THE INVENTION

With the semiconductor device 100 described in Japanese Laid-open patent publication NO. 2001-7278, it is possible to eliminate the necessity of directly electrically connecting the second semiconductor chip 108 and the interconnections on the substrate 102 through bonding wires as in conventional semiconductor devices. This can reduce the lengths of bonding wires, thereby alleviating the occurrence of wire sweep when molding the stacked semiconductor chips are molded an encapsulating resin. However, in the case of the semiconductor device described in Patent Document 1, it is necessary to provide the interconnection sheet 106 between the first semiconductor chip 104 and the second semiconductor chip 108. Therefore, in order to provide, to the interconnection sheet itself, strength enough for withstanding cutting and attachment, it is necessary to make the thickness of the interconnection sheet great, thus resulting in an increase of the thickness of the semiconductor package. Therefore, there has been a need for semiconductor devices having reduced semiconductor-package thicknesses in semiconductor device having stack-type MCP structures or SIP structures.

According to the present invention, there is provided a semiconductor device, in order to overcome the aforementioned problems, including a substrate having interconnections thereon, a first semiconductor chip mounted on the substrate such that the device formation surface thereof is faced to the substrate and a second semiconductor chip mounted on the first semiconductor chip; wherein said first semiconductor chip has an interconnection layer, which is electrically connected to the interconnections of substrate, on the back surface facing said second semiconductor chip.

With the aforementioned semiconductor device, it is possible to electrically connect the second semiconductor chip to the interconnections on the substrate through the interconnection layer, which may eliminate the necessity of providing an interconnection sheet, thereby enabling the thickness of the entire package to reduce.

According to the present invention, since the interconnection layer electrically connected to the interconnections on the substrate is provided on the back surface of the first semiconductor chip which is mounted on the substrate with interconnections thereon such that the device formation surface thereof is faced to the substrate, there is realized a semiconductor device which is reduced thickness of entire semiconductor-package.

### BRIEF DESCRIPTION OF THE DRAWINGS

The above and other objects, advantages and features of the present invention will be more apparent from the following description taken in conjunction with the accompanying drawings, in which:

FIGS. 1A and 1B are schematic cross-sectional views illustrating a semiconductor device according to a first embodiment of the present invention;

FIG. 2A is a schematic top view of the electrical connection layer in the semiconductor device according to the first embodiment of the present invention and FIG. 2B is a schematic cross-sectional view taken along the line a-a in FIG. 2A;

FIGS. 3A to 3E are schematic cross-sectional views schematically illustrating processes for forming the first semiconductor chip;

FIG. 4 is a schematic view illustrating a substantially-round shaped wafer having plural first semiconductor chips formed thereon, seen from the back surface thereof;

FIG. 5A is a schematic top view of a first semiconductor chip in a semiconductor device according to a second embodiment of the present invention and FIG. 5B is a schematic cross-sectional view taken along the line b-b in FIG. 5A;

FIG. 6A is a schematic top view of a first semiconductor chip in a semiconductor device according to a third embodiment of the present invention and FIG. 6B is a schematic cross-sectional view taken along the line c-c in FIG. 6A; and

FIGS. 7A and 7B are schematic cross-sectional views of a conventional semiconductor device.

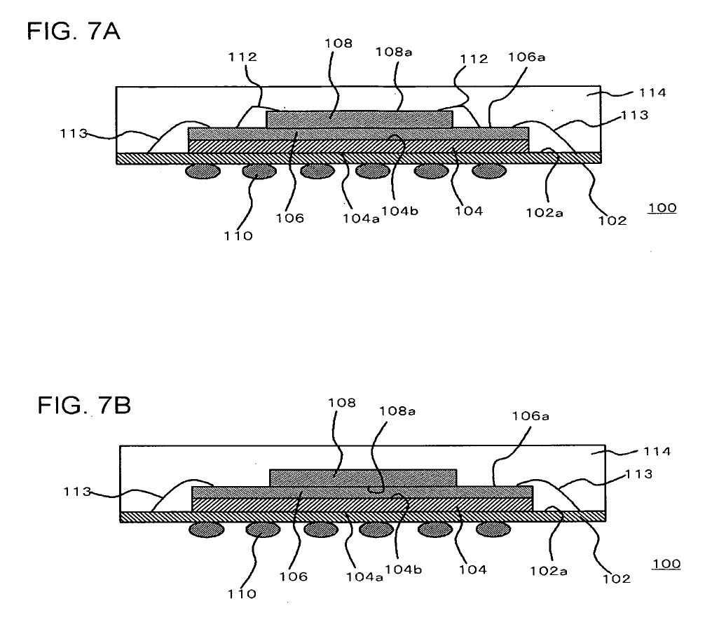

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, embodiments of the present invention will be described by using the drawings. In all the drawings, same components are designated by the same symbols and explanation thereof will not be properly described.

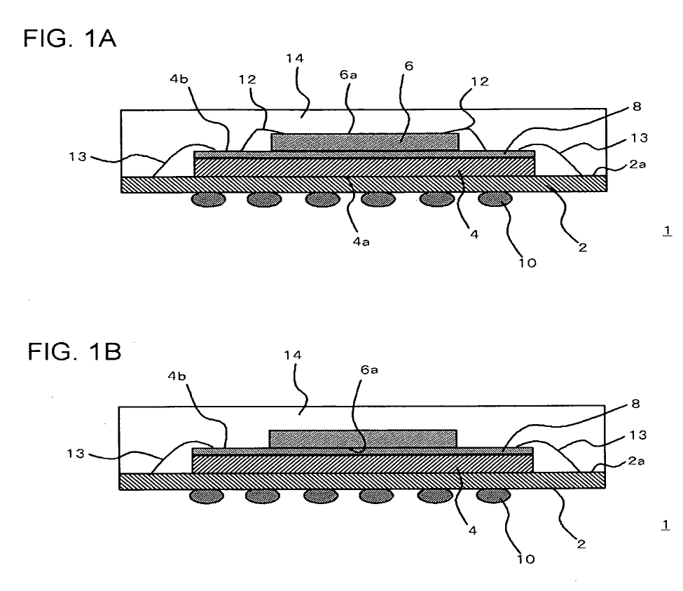

FIG. 1 is a schematic cross-sectional view illustrating a semiconductor device according to a first embodiment of the present invention.

As illustrated in FIG. 1A, a semiconductor device 1 includes a first semiconductor chip 4 and a second semiconductor chip 6 which are stacked in the mentioned order, on a substrate 2 having interconnections thereon. An electrical connection layer 8 is provided on the back surface 4b of the first semiconductor chip 4 which faces to the second semiconductor chip 6, and the electrical connection layer 8 includes an interconnection layer which is electrically connected to the interconnections on the substrate 2.

The substrate 2 includes, on the surface thereof at one side, solder balls 10 which are connecting members used for mounting it onto a printed circuit board. Further, on the mounting surface 2a of the substrate 2 which is the opposite surface, interconnections are formed and also the first semiconductor chip 4 is flip-chip-mounted through bumps (not shown) on the mounting surface 2a such that the device formation surface 4a thereof is faced to the substrate 2. The electrical connection layer 8 is formed on the back surface 4b of the first semiconductor chip 4, and the second semiconductor chip 6 is mounted on the electrical connection layer 8 such that the device formation surface 6a thereof is upwardly faced. The electrical connection layer 8 includes an interconnection layer so that the second semiconductor chip 6 and the interconnections on the substrate 2 can be electrically connected to each other through the interconnection layer.

As described above, the first semiconductor chip 4 is flip-chip-mounted on the mounting surface 2a of the substrate 2. This enables easily electrical connection to establish between the first semiconductor chip 4 and the interconnections on the substrate 2 without using bonding wires. On the other hand, if the first semiconductor chip is merely flip-chip-mounted as in the conventional semiconductor device, it will be necessary to directly electrically connect the second semiconductor chip mounted on the first semiconductor chip to the interconnections on the substrate. This will require longer bonding wires and thus will cause wire sweep during molding the semiconductor chips by the encapsulating resin, thereby resulting in contacts with other bonding wires and the risk of wire breakage. However, in the present embodiment, the electrical connection layer 8 including the interconnection layer is formed on the back surface 4b of the first semiconductor chip 4 so that the second semiconductor chip 6 can be electrically connected to the interconnections on the substrate 2 through the interconnection layer. This can avoid contacts with other bonding wires and wire breakage.

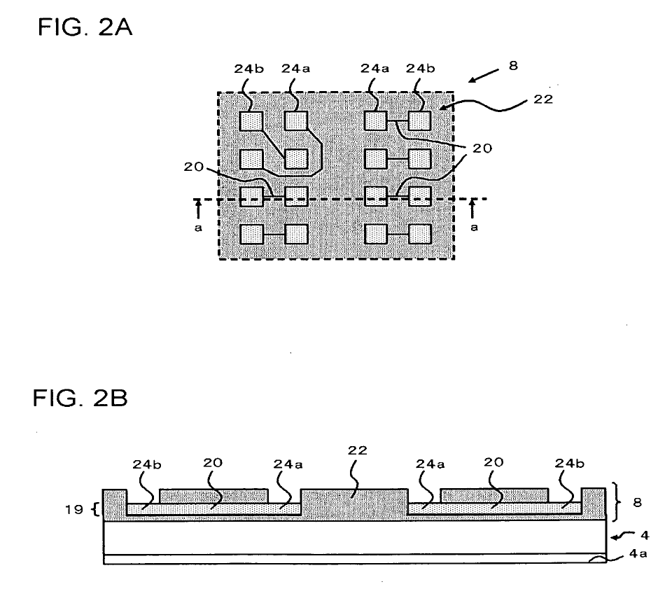

FIG. 2 illustrates the electrical connection layer 8 formed on the first semiconductor chip 4. FIG. 2A is a schematic top view of the electrical connection layer 8 and FIG. 2B is a schematic cross-sectional view taken along the line a-a in FIG. 2A. As illustrated in FIG. 2B, the electrical connection layer 8 is constituted by an interconnection layer 19 and an insulating layer 22 which are stacked into a desired structure. As illustrated in FIG. 2A, the interconnection layer 19 is constituted by first interconnection pad portions 24a and second interconnection pad portions 24b which are upwardly opened and interconnections 20 electrically connecting these pad portions 24a and 24b, which are provided at predetermined positions in the insulating layer 22. As illustrated in FIG. 2, it is possible to establish electrical connection between the first interconnection pad portions 24a electrically connected to the second semiconductor chip 6 and desired second interconnection pad portions 24b through the interconnections 20. Therefore, This enables the second semiconductor chip 6 is electrically connected to desired positions of the mounting surface 2a of the substrate 2.

With the aforementioned structure of the interconnection layer 19, it is possible to reduce the number of interconnection layers on the substrate 2 and also reduce the area of the mounting surface 2a. In cases where plural chips are stacked in conventional semiconductor devices, there has been a need for provision of interconnections on the substrate 2 for bringing pads with the same functions (GNDs and power supplies) as close to one another as possible. Namely, when pads with the same functions are separated from one another, they are connected to different positions (separated positions) of the substrate 2, which necessitates forming, on the substrate 2, interconnections for comprehensively deriving them to the outside (the printed circuit board). This structure causes an increase of the number of interconnection layers on the substrate 2, and an increase of the area of the mounting surface 2a. On the contrary, with the semiconductor device 1 according to the present application, it is possible to route interconnections through the interconnection layer 19, thereby enabling plural pads with the same functions to bring close to one another. This can reduce the number of interconnections on the substrate 2 for comprehensively deriving these pads to the outside, thereby reducing the number of interconnection layers and also reducing the area of the mounting surface 2a of the substrate 2.

The structure of the electrical connection layer 8 and the method of fabricating the same will be described later.

The electrical connection between the second semiconductor chip 6 and the interconnection layer 19 can be established by connecting, through bonding wires 12, bonding pads (not shown) provided on the device formation surface 6a of the second semiconductor chip 6 to bonding pads (not shown) provided on the first interconnection pad portions 24a of the interconnection layer 19.

On the other hand, the electrical connection between the interconnection layer 19 and the interconnections on the second substrate 2 is established by connecting, through bonding wires 13, bonding pads (not shown) formed on the second interconnection pad portions 24b of the interconnection layer 19 to bonding pads (not shown) formed on the mounting surface 2a of the substrate 2.

As described above, in the interconnection layer 19, the first interconnection pad portions 24a and the second interconnection pad portions 24b are electrically connected through the interconnections 20. Consequently, the second semiconductor chip 6 is electrically connected to the interconnections on the substrate 2.

After the first semiconductor chip 4 and the second semiconductor chip 6 are mounted on the substrate 2 as described above, the chips is molded by the encapsulating resin 14 to complete the formation of the semiconductor device 1 according to the present embodiment.

Also, as illustrated in FIG. 1B, bumps may be formed on the device formation surface 6a of the second semiconductor chip 6 and the bumps may be connected to the first interconnection pad portions 24a to electrically connect the second semiconductor chip 6 and the interconnection layer 19 to each other. The electrical connection between the interconnection layer 19 and the interconnections on the substrate 2 is established by connecting, through the bonding wires 13, the bonding pads (not shown) formed on the second interconnection pad portions 24b of the interconnection layer 19 to the bonding pads (not shown) formed on the mounting surface 2a of the substrate 2.

In the aforementioned first embodiment, the first semiconductor chip 4 having the electrical connection layer 8 formed thereon may be fabricated as follows.

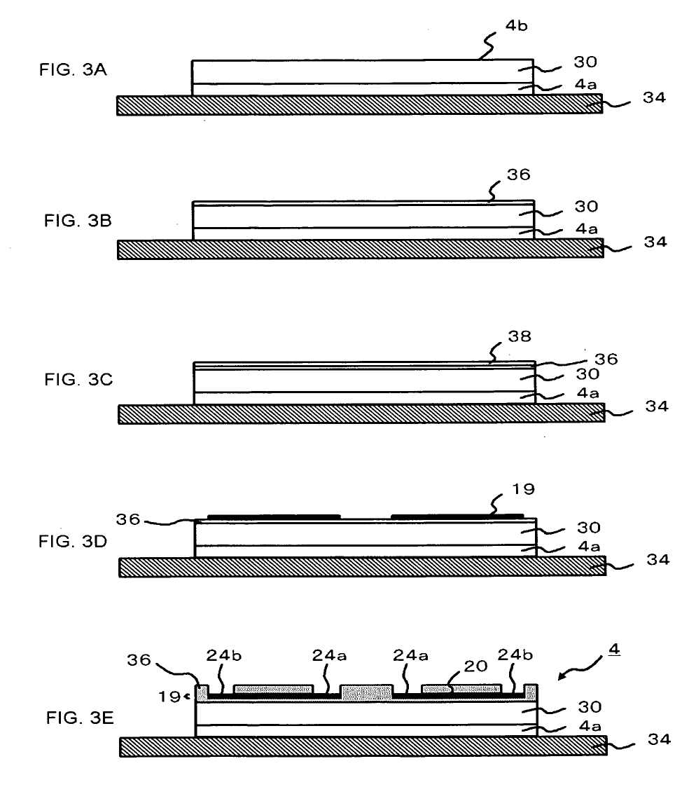

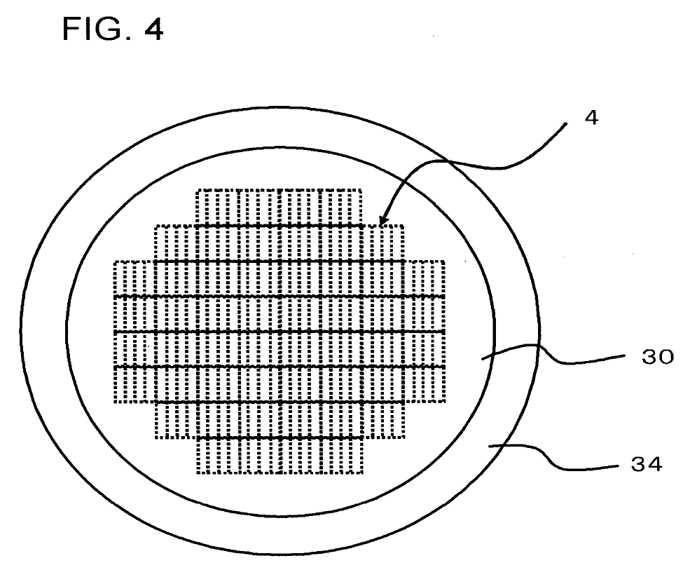

FIG. 3 is schematic cross-sectional views schematically illustrating processes for forming the first semiconductor chip 4. While there is illustrated, in FIG. 3, only a single first semiconductor chip 4, in actual, plural first semiconductor chips 4 are concurrently formed at a wafer state and then separated therefrom through dicing to provide individual first semiconductor chips 4. Namely, as illustrated in a schematic top view (a view from the back surface) of FIG. 4, a substantially-round shaped wafer 30 is attached to a supporting sheet 34 at the surface thereof, namely at the device forming surface thereof. Then, an interconnection layer is formed on the back surface of the wafer 30 at the wafer state, in correspondence with the regions of the device formation surface on which respective semiconductor chips 4 are to be formed. As described above, plural first semiconductor chips 4 including the interconnection layer formed on the back surfaces are concurrently formed and then separated from one another, through dicing, to provide the respective first semiconductor chips 4. Hereinafter, these processes will be described in order.

As illustrated in FIG. 3A, a wafer 30 including semiconductor devices formed thereon is attached to a supporting sheet 34 through an adhesive or the like such that the device formation surface 4a thereof is faced to the supporting sheet 34, and then polishing is applied, with a conventional method, to the surface opposite to the device formation surface, namely the back surface 4b. The wafer 30 is a substantially-round shaped silicon substrate. The supporting sheet 34 has excellent adhesiveness for protecting the device formation surface 4a during the process of polishing the back surface 4b and the process of forming back-surface interconnections which will be described later and also has excellent chemical resistance and excellent heat resistance during the process of forming the back-surface interconnections.

Next, as illustrated in FIG. 3B, an insulating layer 36 with a film thickness of about several micrometers is formed on the back surface 4b of the wafer 30, with a conventional CVD method. The insulating layer 36 may be formed by using a coating liquid made of silica or the like. The insulating layer 36 is made of SiO₂, SiN or the like.

After the insulating layer 36 is formed on the back surface 4b of the wafer 30, as illustrated in FIG. 3C, a metal film 38 with a film thickness of about several micrometers is formed on the surface of the insulating layer 36 by a metal sputtering method, plating method or the like. The metal film 38 may be a metal film made of Al, Cu or the like or a composite film made of TiN/Al—Cu or the like. Also, the metal film 38 may be made of any other conductive materials.

Next, as illustrated in FIG. 3D, the metal film 38 is patterned with a conventional method to form an interconnection layer 19 with a predetermined shape on the surface of the insulating layer 36. The interconnection layer 19 is formed on the regions of the back surface which correspond to the regions of first semiconductor chips 4 are to be formed. By the patterning, the interconnection layer 19 as illustrated in FIG. 2 is provided so that desired first interconnection pad portions 24a and desired second interconnection pad portions 24b can be electrically connected through interconnections 20. This can reduce the number of interconnection layers on the substrate 2 and also can reduce the area of the mounting surface 2a of the substrate 2, as previously described.

While in the present embodiment the patterning of the metal film after the formation thereof has been described as an example of the formation flow, it is possible to form interconnect trenches in the insulating layer 36, then form a metal film such that it covers the entire back surface 4b similarly to in aforementioned embodiment and then apply polishing to the back surface again to form embedded type interconnections.

After the formation of the interconnection layer 19, a second insulating film with a thickness of several micrometers is formed on the entire back surface 4b such that it covers the interconnection layer 19. Then, etching is applied to the second insulating film. By the etching, predetermined positions is opened to form first interconnection pad portions 24a and second interconnection pad portions 24b. With the processing, as illustrated in FIG. 3E, the interconnection layer 19 is formed on the back surface 4b of the wafer 30. The interconnection layer 19 includes the first interconnection pad portions 24a, the second interconnection pad portions 24b and interconnections 20 which electrically connect them to one another.

Subsequently, the supporting sheet 34 is detached and dicing is applied to the wafer 30 for separating the respective chips therefrom with a conventional method to provide first semiconductor chips 4 with the interconnection layer on the back surface thereof.

Subsequently, there will be described the effects of the semiconductor device 1 according to the present embodiment.

In the semiconductor device 1 according to the present embodiment, the first semiconductor chip 4 is mounted on the substrate 2 having interconnections thereon such that the device formation surface 4a is faced to the substrate 2, and the interconnection layer 19 electrically connected to the interconnections on the substrate 2 is provided on the back surface 4b of the first semiconductor chip 4. Accordingly, the second semiconductor chip 6 can be electrically connected to the interconnections on the substrate 2 through the interconnection layer 19. On the other hand, in the case of the semiconductor device described in Japanese Laid-open patent publication NO. 2001-7278, it is necessary to electrically connect the second semiconductor chip and the substrate through the interconnection sheet. In this case, in order to maintain the strength of the interconnection sheet, it is necessary to make the film thickness thereof great. On the contrary, in the semiconductor device 1 according to the present embodiment, the electrical connection layer 8 is formed directly on the back surface 4b which has been subjected to polishing, which can maintain the strength of the first semiconductor chip 4 itself. This enables reducing the layer thickness of the electrical connection layer 8 in comparison with the aforementioned interconnection sheet. This enables the thickness of the entire semiconductor package to reduce. Therefore, the semiconductor device according to the present embodiment can be suitably utilized in a semiconductor device having a stack type MCP structure or a SIP structure. Further, in the semiconductor device 1 according to the present embodiment, the electrical connection layer 8 is formed on the back surface 4b of the first semiconductor chip 4. This enables a balance to strike between the linear expansion coefficients of the device formation surface 4a and the electrical connection layer, thereby alleviating warpage of the wafer and the semiconductor chip.

Further, in the semiconductor device 1 according to the present embodiment, the interconnection layer 19 is provided on the back surface 4a of the first semiconductor chip 4, and the second semiconductor chip 6 is electrically connected to the interconnections on the substrate 2 through the interconnection layer 19. Accordingly, there is no need for providing bonding wires for directly electrically connecting the second semiconductor chip 6 and the interconnections on the substrate 2, in the semiconductor device 1 according to the present embodiment illustrated in FIG. 1A.

On the other hand, in the conventional semiconductor device, it is necessary to directly electrically connect the second semiconductor chip and the interconnections on the substrate through bonding wires. Accordingly, in cases where there is a large area difference between the first semiconductor chip and the second semiconductor chip, there is a need for employing significantly longer bonding wires for electrically connecting the second semiconductor chip to the interconnections on the substrate. When longer bonding wires are employed as described above, wire sweep is generated when the semiconductor chip is molded by the encapsulating resin. This results in contact with other bonding wires and the risk of wire breakage. Further, in order to enable wire bonding over a large distance, the bonding wires are required to have an upward height, thus resulting in an increase of the thickness of the package. Therefore, there has been a need for semiconductor devices having reduced package thicknesses.

On the other hand, in the semiconductor device 1 according to the present embodiment, the interconnection layer 19 is provided on the back surface 4b of the first semiconductor chip 4. Namely, in the semiconductor device 1 according to the present embodiment illustrated in FIG. 1A, in order to electrically connect the second semiconductor chip 6 and the substrate 2, the second semiconductor chip 6 and the interconnection layer 19 can be electrically connected to each other through bonding wires and, further, the interconnection layer 19 and the interconnections on the substrate 2 can be electrically connected through bonding wires. In the semiconductor device 1 according to the present embodiment illustrated in FIG. 1B, there is no need for providing bonding wires for electrically connecting the second semiconductor chip 6 and the interconnection layer 19. This eliminates the necessity of increasing the lengths of bonding wires even when there is a large area difference between the first semiconductor chip 4 and the second semiconductor chip 6 (or bonding wires are not necessary), which can prevent the occurrence of wire sweep and also can reduce the thickness of the package.

By using the semiconductor chip including the interconnection layer 19 provided on the back surface 4b thereof as described above, it is possible to eliminate the restriction on the chip size, thereby increasing the flexibility of the combination of semiconductor chips in semiconductor devices having an MCP or SIP construction.

Hereinafter, there will be described other embodiments of the semiconductor device 1 according to the present embodiment. The embodiments are different from the first embodiment in the structure of the electrical connection layer 8. Therefore, explanation of the other portions will not be described and the structure of the electrical connection layer 8 will be described.

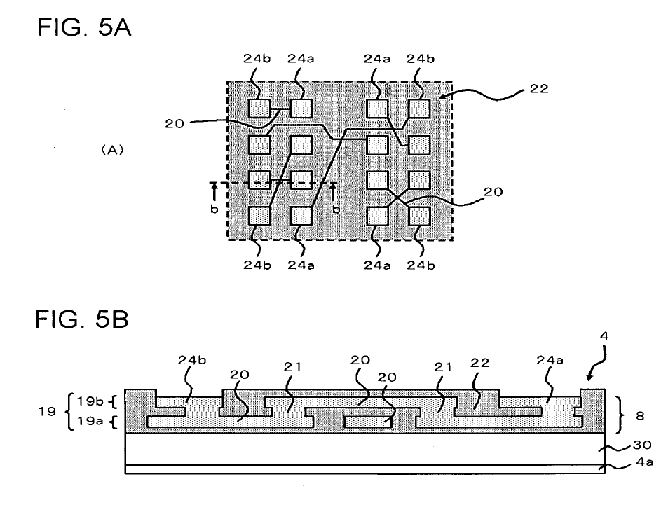

FIG. 5 illustrates a semiconductor device 1 according to a second embodiment of the present embodiment.

FIG. 5A is a schematic top view of a first semiconductor chip 4 including an electrical connection layer 8 and FIG. 5B illustrates a schematic cross-sectional view taken along the line b-b in FIG. 5A. As illustrated in FIG. 5B, the electrical connection layer 8 is constituted by an interconnection layer 19 and an insulating layer 22 which are stacked into a desired structure. The interconnection layer 19 has a two-layer structure consisting of a first interconnection layer 19a and a second interconnection layer 19b as illustrated in FIG. 5B.

The second interconnection layer 19b is constituted by first interconnection pad portions 24a and second interconnection pad portions 24b which are upwardly opened, and interconnections 20 which electrically connect these pad portions 24a and 24b to one another. On the other hand, the first interconnection layer 19a is constituted by interconnections 20. The first interconnection layer 19a and the second interconnection layer 19b are electrically connected to each other through via plugs 21. This increases the flexibility of the combination of back-surface interconnections, thereby easily selecting of electrical connections between first interconnection pad portions 24a and second interconnection pad portions 24b in comparison with the first embodiment.

The interconnection layer 19, the interconnections 20, the insulating layer 22, the first interconnection pad portions 24a and the second interconnection pad portions 24b are formed by properly selecting the aforementioned methods and the via plugs 21 are formed with a conventional damascene process.

While, in the second embodiment, there has been described, as an example, the interconnection layer 19 consisting of two layers, the interconnection layer 19 is not particularly limited thereto and may be constituted by stacked three layers.

Next, there will be described a semiconductor device 1 according to a third embodiment of the present embodiment.

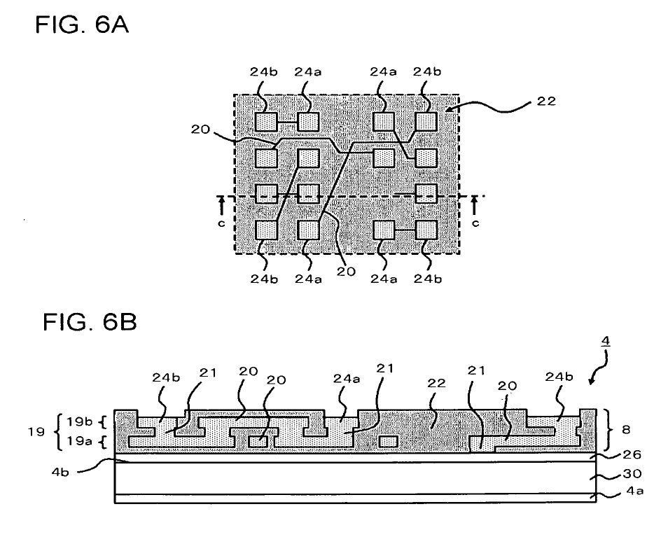

FIG. 6A is a schematic top view of a first semiconductor chip 4 including an electrical connecting layer 8 and FIG. 6B illustrates a schematic cross-sectional view taken along the line c-c in FIG. 6A. As illustrated in FIG. 6B, in the first semiconductor chip 4, a back-surface electrode layer 26 is formed on the entire back surface 4b of the wafer 30 and an electric connection layer 8 is stacked on the upper surface thereof. The electric connecting layer 8 includes an interconnection layer 19, and the interconnection layer 19 is constituted by two layers which are a first interconnection layer 19a and a second interconnection layer 19b. The first interconnection layer 19a and the second interconnection layer 19b are electrically connected to each other through via plugs 21. Further, the back-surface electrode layer 26 and the first interconnection layer 19a are electrically connected to each other through via plugs 21. Further, the back-surface electrode layer 26 is connected to a DC voltage supply, not shown, to enable a bias voltage to apply to the wafer 30 for driving transistors.

By forming the back-surface electrode layer 26 on the entire back surface 4b and electrically connecting the back-surface electrode layer 26 to the interconnection layer 19 as described above, it is possible to stack semiconductor devices having back-surface electrodes in a MCP or SIP structure, which can widen the range of selection of semiconductor chips to be stacked therein. Further, the back-surface electrode 26 can be properly patterned as required.

The interconnection layer 19, the interconnections 20, the via plugs 21, the insulating layer 22, the first interconnection pad portions 24a and the second interconnection pad portions 24b are formed with the aforementioned method and the back-surface electrode layer 26 is formed with a conventional method.

While in the third embodiment there has been described as an example of the interconnection layer 19 consisting of two layers, the interconnection layer 19 is not particularly limited thereto and is only required to consist of one or more layers.

While embodiments of the present embodiment have been described with reference to the drawings, these embodiments are merely illustrative of the present embodiment and various structures other than the aforementioned structures may be employed.

For example, while there have been described cases where the interconnection layer 19 formed on the first semiconductor chip 4 is electrically connected to the interconnections on the substrate 2 through the bonding wires 13 in the aforementioned embodiments, it is also possible to provide through electrodes in the first semiconductor chip 4 to electrically connect the interconnection layer 19 formed on the first semiconductor chip 4 to the interconnections on the substrate 2 without using bonding wires 13.

While there have been described the semiconductor devices constituted by the first semiconductor chip 4 and the second semiconductor chip 6 which are stacked in order on the substrate in the aforementioned embodiments, it is possible to employ plural semiconductor chips including an interconnection layer 19 and stack the semiconductor chips in three or more layers.

It is apparent that the present embodiment is not limited to the above embodiment, that may be modified and changed without departing from the scope and spirit of the invention.

What is claimed is:

1. A semiconductor device comprising a substrate having interconnections, a first semiconductor chip mounted on the substrate such that its device formation surface is faced to the substrate and a second semiconductor chip mounted on the first semiconductor chip;
wherein said first semiconductor chip has an interconnection layer, which is electrically connected to the interconnections of substrate, on the back surface facing said second semiconductor chip.

2. The semiconductor device according to claim 1, wherein said interconnection layer is constituted by a patterned metal layer.

3. The semiconductor device according to claim 1, wherein plural interconnection layers are provided and these interconnection layers are electrically connected to one another through via plugs.

4. The semiconductor device according to claim 1, wherein said interconnection layer and the interconnection on said substrate are electrically connected through bonding wires.

5. The semiconductor device according to claim 1, wherein said second semiconductor chip and the interconnections on said substrate are electrically connected through said interconnection layer.

6. The semiconductor device according to claim 5, wherein said second semiconductor chip and said interconnection layer are electrically connected to each other through bonding wires.

7. The semiconductor device according to claim 1, wherein said second semiconductor chip is mounted on said interconnection layer such that its device formation surface is faced to the interconnection layer and said second semiconductor chip and said interconnection layer are electrically connected to each other.
